(19) United States
(12) Patent Application Publication
(10) Pub. No.: US 2015/0015119 A1
(43) Pub. Date: Jan. 15, 2015

(54) PIEZOELECTRIC VIBRATING PIECE, METHOD FOR FABRICATING PIEZOELECTRIC VIBRATING PIECE, PIEZOELECTRIC DEVICE, AND METHOD FOR FABRICATING PIEZOELECTRIC DEVICE

(71) Applicant: NIHON DEMPA KOGYO CO., LTD., Tokyo (JP)

(72) Inventors: TAKEHIRO TAKAHASHI, SAITAMA (JP); KUNIO MORITA, SAITAMA (JP); SHUICHI MIZUSAWA, SAITAMA (JP); TAICHI HAYASAKA, SAITAMA (JP)

(21) Appl. No.: 14/324,046

(22) Filed: Jul. 3, 2014

(30) Foreign Application Priority Data
Jul. 11, 2013 (JP) 2013-145079

(51) Int. Cl. H03H 9/17; H03H 3/02

(52) U.S. Cl. CPC H03H 9/17; H03H 3/02
USPC 310/348; 29/25.35

(57) ABSTRACT

A piezoelectric vibrating piece includes a vibrating portion, a framing portion, and a connecting portion. The framing portion surrounds the vibrating portion. The connecting portion connects the vibrating portion and the framing portion. The connecting portion includes an inclined surface disposed on at least one of a front surface and a back surface of the connecting portion. A boundary between the inclined surface and a flat surface is established in a middle region that is away from a connecting region of the connecting portion and the vibrating portion, and is away from a connecting region of the connecting portion and the framing portion.

### CROSS REFERENCE TO RELATED APPLICATION

This application claims the priority benefit of Japan application serial no. 2013-145079, filed on Jul. 11, 2013. The entirety of the above-mentioned patent application is hereby incorporated by reference herein and made a part of this specification.

### TECHNICAL FIELD

This disclosure relates to a piezoelectric vibrating piece, a method for fabricating the piezoelectric vibrating piece, a piezoelectric device, and a method for fabricating the piezoelectric device.

### DESCRIPTION OF THE RELATED ART

Electronic equipment such as a mobile terminal and a mobile phone includes a piezoelectric device such as a crystal unit and a crystal controlled oscillator. Such a piezoelectric device includes a lid, a base and, and a piezoelectric vibrating piece such as a quartz-crystal piece. The piezoelectric vibrating piece includes a vibrating portion, a framing portion, and a connecting portion, and is made of, for example, an AT-cut quartz-crystal material by etching. The vibrating portion vibrates at a predetermined vibration frequency. The framing portion surrounds the vibrating portion. The connecting portion connects the vibrating portion and the framing portion. The lid is bonded to the front surface of the framing portion of the piezoelectric vibrating piece via a bonding material, while the base is similarly bonded to the back surface of the framing portion via a bonding material (see Japanese Unexamined Patent Application Publication No. 2012-147228).

Incidentally, a structure of the piezoelectric vibrating piece having the framing portion is formed as follows. First, the thickness of the vibrating portion is adjusted, and then a through-hole is opened to form the connecting portion, which connects the vibrating portion and the framing portion. Wet-etching of the predetermined region of the quartz-crystal material, for adjusting the thickness of the vibrating portion, may form an inclined surface at a boundary between the predetermined region and the peripheral region due to the crystallographic axis of the quartz-crystal material. In addition, the through-hole is opened by wet-etching after the front surface of the piezoelectric vibrating piece is covered with a mask pattern. At this time, if a curved line of the mask pattern is disposed at a boundary between the inclined surface and a flat surface, the etching extends to the inside of the masked region (the back surface side of the mask) along the inclined surface during wet-etching, which disadvantageously erodes a part of the connecting portion and the framing portion. This results in decrease in rigidity of the connecting portion, and decrease in shock resistance of the piezoelectric vibrating piece.

A need thus exists for a piezoelectric vibrating piece, a method for fabricating the piezoelectric vibrating piece, a piezoelectric device, and a method for fabricating the piezoelectric device which are not susceptible to the drawback mentioned above.

### SUMMARY

A piezoelectric vibrating piece according to the disclosure includes a vibrating portion, a framing portion, and a connecting portion. The framing portion surrounds the vibrating portion. The connecting portion connects the vibrating portion and the framing portion. The connecting portion includes an inclined surface disposed on at least one of a front surface and a back surface of the connecting portion. A boundary between the inclined surface and a flat surface is established in a middle region that is away from a connecting region of the connecting portion and the vibrating portion, and is away from a connecting region of the connecting portion and the framing portion.

### BRIEF DESCRIPTION OF THE DRAWINGS

The foregoing and additional features and characteristics of this disclosure will become more apparent from the following detailed description considered with reference to the accompanying drawings.

FIG. 1A is a plan view illustrating a piezoelectric vibrating piece according to a first embodiment.

FIG. 1B is a cross-sectional view taken along the line IB-IB of FIG. 1A.

FIG. 2 is an enlarged plan view illustrating a main part of the piezoelectric vibrating piece illustrated in FIGS. 1A and 1B.

FIGS. 3A to 3F illustrate a fabrication process of the piezoelectric vibrating piece illustrated in FIGS. 1A and 1B.

FIG. 4A is a photograph of a configuration of piezoelectric wafer according to a comparative example.

FIG. 4B is a photograph of a configuration of piezoelectric wafer according to a reference example.

FIG. 5 is an exploded perspective view illustrating a piezoelectric device according to the embodiment.

FIG. 6 is a flowchart illustrating a fabrication process of the piezoelectric device.

FIG. 7 is a view illustrating a fabrication process of a piezoelectric wafer.

FIG. 8 is a view illustrating a fabrication process of a lid wafer.

FIG. 9 is a view illustrating a fabrication process of a base wafer.

### DETAILED DESCRIPTION

In the following description, the embodiments of this disclosure are described with reference to the drawings. Note that, this disclosure is not limited to these embodiments. In addition, the drawings are appropriately scaled, for example, partially enlarged or highlighted to describe the embodiments. In the following description, the directions illustrated in each drawing use the XYZ coordinate system. In the XYZ coordinate system, a plane parallel to a front surface of a piezoelectric vibrating piece is as the XZ plane. In the XZ plane, a longitudinal direction of the piezoelectric vibrating piece is as the X direction, and a direction perpendicular to the X direction is as the Z direction. A direction perpendicular to the XZ plane (thickness direction of piezoelectric vibrating piece) is as the Y direction. The explanations are given assuming that the positive direction corresponds to a direction that is indicated by the arrow, and the negative direction corresponds to a direction opposite to the positive direction in each of the X, Y, and Z direction.

### Piezoelectric Vibrating Piece

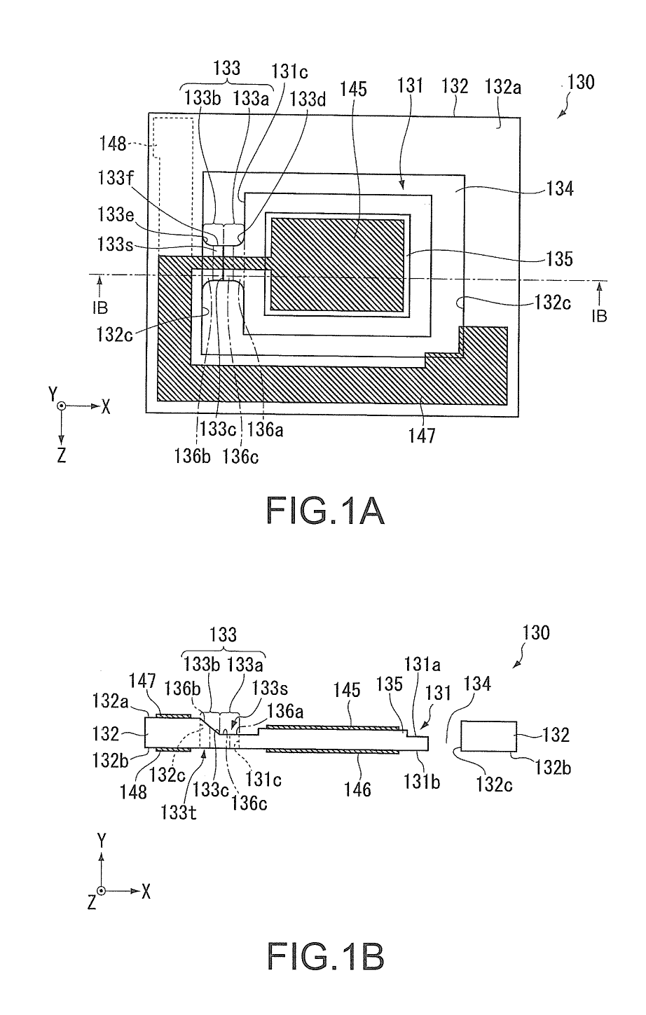

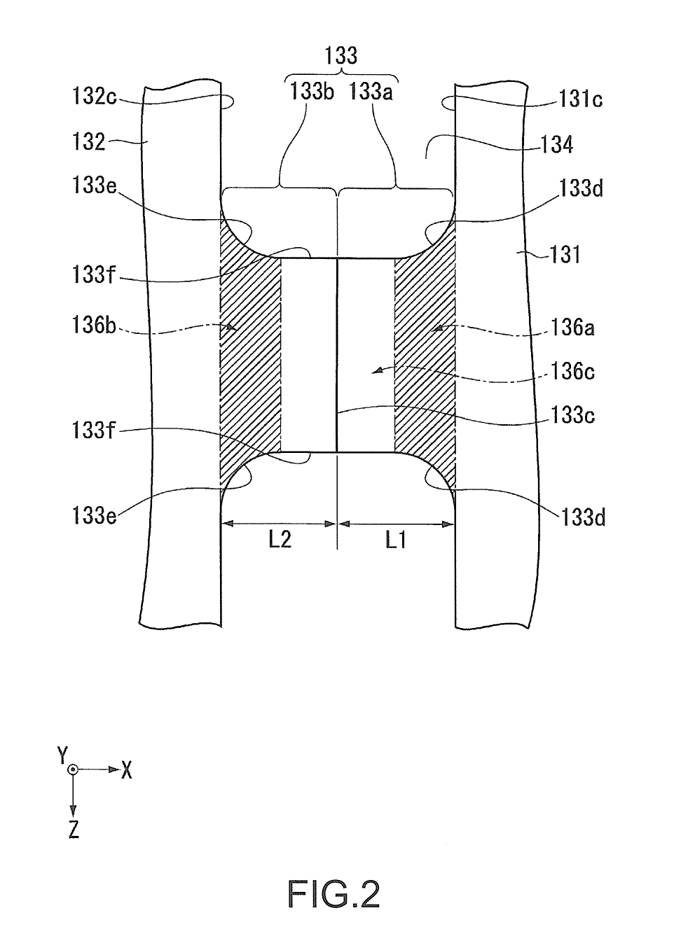

In the following description, a piezoelectric vibrating piece 130 according to this embodiment is described with reference to FIG. 1A to FIG. 2. Note that, FIG. 2 is an enlarged plan view that mainly illustrates a connecting portion 133 of the piezoelectric vibrating piece 130, and omits metal films (such as an extraction electrode). As illustrated in FIG. 1A, the piezoelectric vibrating piece 130 includes a vibrating portion 131, a framing portion 132, and the connecting portion 133. The vibrating portion 131 vibrates at a predetermined vibration frequency, the framing portion 132 surrounds the vibrating portion 131, and the connecting portion 133 connects the vibrating portion 131 and the framing portion 132. A through-hole 134, which passes through the piezoelectric vibrating piece 130 in the Y-axis direction, is disposed between the vibrating portion 131 and the framing portion 132, except the connecting portion 133.

The piezoelectric vibrating piece 130 is made of, for example, an AT-cut quartz-crystal piece. An AT-cut method can advantageously obtain excellent frequency characteristics, when a piezoelectric device such as a crystal unit and a crystal controlled oscillator is used at near ordinary temperature. The AT-cut method is a cutting method for cutting out a quartz-crystal at an angle inclined by 35°15′ around the crystallographic axis with respect to the optical axis of the three crystallographic axes of a synthetic quartz crystal, which are the electrical axis, the mechanical axis, and the optical axis. Note that, the piezoelectric vibrating piece 130 is not limited to a quartz-crystal piece, and any other piezoelectric materials such as a lithium tantalate and a lithium niobate may be used.

The vibrating portion 131 has a rectangular shape, which has a long side in the X-axis direction and a short side in the Z-axis direction, when the vibrating portion 131 is viewed from the Y direction. The vibrating portion 131 also has a thickness in the Y-axis direction thinner than that of the framing portion 132. Note that, the vibrating portion 131 is thinned by being deleted from the front surface side. However, it should not be construed in a limiting sense. The vibrating portion 131 may be thinned by being deleted from the back surface side. In addition, the vibrating portion 131 includes a mesa 135 in which the central portion is thicker than the peripheral portion. The mesa 135 is not limited to being disposed on the front surface (+Y-side surface) of the vibrating portion 131, and the mesas 135 may be also respectively disposed on, for example, the front and back surfaces (−Y-side surface) of the vibrating portion 131.

The framing portion 132 has a rectangular shape that generally has a long side in the X-axis direction and a short side in Z-axis direction. A front surface (+Y-side surface) 132a and a back surface (−Y-side surface) 132b of the framing portion 132 are respectively bonded to a bonding surface 112 of the lid 110 and a bonding surface 122 of the base 120, which are described later.

The connecting portion 133 connects the vibrating portion 131 and the framing portion 132. A flat surface 133a and an inclined surface 133b are disposed on a front surface of the connecting portion 133. The flat surface 133a is the identical surface as a front surface 131a (periphery portion of mesa 135) of the vibrating portion 131. A boundary portion 133c is disposed between the flat surface 133a and the inclined surface 133b. The inclined surface 133b extends from the boundary portion 133c toward the framing portion 132 in such way as to gradually increase the thickness (dimension in the Y direction) of the connecting portion 133. The inclined surface 133b is not limited to a flat surface. The inclined surface 133b may partially or entirely have curved surface.

A connecting region 136a is established between the connecting portion 133 and the vibrating portion 131. Meanwhile, a connecting region 136b is established between the connecting portion 133 and the framing portion 132. A middle region 136c is established between the connecting region 136a and connecting region 136b. The connecting regions 136a and 136b are established as regions in which stress concentration is easily caused at pods, if the surface of connecting portion 133 get damage such as the pods. Accordingly, each of connecting regions 136a and 136b changes its area depending on a material of the piezoelectric vibrating piece 130 and the width of the connecting portion 133 in the Z direction. In addition, in FIG. 2 the areas of the connecting region 136a and the connecting region 136b are approximately equal. However, it should not be construed in a limiting sense. The connecting region 136a and the connecting region 136b can be established as different areas.

The boundary portion 133c is disposed in the middle region 136c. The boundary portion 133c is a straight line parallel to the Z direction. However, it should not be construed in a limiting sense. The boundary portion 133c may be a line that is oblique with respect to the Z direction or a line that is curved.

The boundary portion 133c is disposed at approximately the center of the connecting portion 133 in the X direction. As illustrated in FIG. 2, a distance L1 in the X direction, which is from the +X-side end of the connecting portion 133 to the boundary portion 133c, is approximately equal to a distance L2 in the X direction, which is from the −X-side the end of the connecting portion 133 to the boundary portion 133c. The boundary portion 133c, however, is not limited to be disposed at approximately the center of the connecting portion 133, and the boundary portion 133c may be disposed at any position, such as, at a position closer to the vibrating portion 131, as long as the boundary portion 133c is disposed in middle region 136c.

As illustrated in FIG. 2, the +X-side end of the connecting portion 133 has two vibrating portion side corner portions 133d. The two vibrating portion side corner portions 133d are disposed at a boundary between a side surface of the connecting portion 133 and a side surface of the vibrating portion 131. The vibrating portion side corner portions 133d are in a rounded shape having a curved line, which is from a side of the connecting portion 133 to the vibrating portion 131.

Also, the −X-side end of the connecting portion 133 has two framing portion side corners 133e. The two framing portion side corner portions 133e are disposed at a boundary between a side surface of the connecting portion 133 and a side surface of the framing portion 132. The framing portion side corner portions 133e are in a rounded shape having a curved line, which is from a connecting portion 133 side to the framing portion 132. Note that, as illustrated in FIG. 2, the connecting regions 136a and 136b respectively include the vibrating portion side corner portions 133d and the framing portion side corner portions 133e, and respectively have shapes whose dimensions in the Z direction gradually increase.

Thus, the vibrating portion side corner portions 133d and the framing portion side corner portions 133e have curved lines, which reduce a stress concentrated at a connecting region between the connecting portion 133 and the vibrating portion 131, and at a connecting region between the connecting portion 133 and the framing portion 132. Thus, rigidity of the respective connecting regions is enhanced. By doing this, a high shock resistance in the connecting portion 133 is provided.

Note that, the vibrating portion side corner portions 133d and the framing portion side corner portions 133e have curved lines as shown in FIG. 2. However, it should not be construed in a limiting sense. The vibrating portion side corner portions 133d and the framing portion side corner portions 133e may have, for example, an orthogonal line. The shapes of the connecting regions 136a and 136b are respectively established corresponding to the vibrating portion side corner portions 133d and the framing portion side corner portions 133e.

As illustrated in FIG. 2, straight line portions 133f are disposed between the respective vibrating portion side corner portions 133d and the framing portion side corner portions 133e. The straight line portions 133f are disposed parallel to an extending direction of the connecting portion 133 (the X direction). The straight line portions 133f extend at side surfaces of the connecting portion 133 from the flat surface 133a to the inclined surface 133b. The boundary portion 133c connects the two straight line portions 133f. Note that, portions where the straight line portions 133f are disposed, have a constant width in the Z direction along the X direction of the connecting portion 133.

In addition, FIG. 1A to FIG. 2 illustrate the front surface side of the vibrating piece 130, the same applies to the back surface side of the vibrating piece 130. That is, when the vibrating portion 131 is thinned at the back surface side of the piezoelectric vibrating piece 130, a boundary formed between the inclined surface and the flat surface on the back surface of the connecting portion 133 is disposed in the middle region between the connecting regions similar to FIG. 2.

As illustrated in FIGS. 1A and 1B, an excitation electrode 145 having a rectangular shape is disposed on a front surface of the mesa 135 (front surface 131a of vibrating portion 131), while an excitation electrode 146 having a rectangular shape is disposed on a back surface 131b of the vibrating portion 131. By applying a predetermined A.C. voltage to the excitation electrodes 145 and 146, the vibrating portion 131 is vibrated at a predetermined vibration frequency. The excitation electrodes 145 and 146 are respectively electrically connected to extraction electrodes 147 and 148.

The extraction electrode 147 extends from the −X-side of the excitation electrode 145 to the −X-side of the front surface 132a of the framing portion 132 via the front surface of the mesa 135, the front surface 131a of the vibrating portion 131, and a front surface 133s of the connecting portion 133. Next, the extraction electrode 147 extends on the front surface 132a of the framing portion 132 in the +Z direction, and turns to the +X direction, then extends to the +X-side and +Z-side region on the front surface 132a of the framing portion 132. Then, the extraction electrode 147 extends to the +X-side and +Z-side of a back surface 132b of the framing portion 132 via an inner side surface 132c of the framing portion 132.

The extraction electrode 148 extends from the −X-side of the excitation electrode 146 to the −X-side of the back surface 132b of the framing portion 132 via a back surface 135b of the mesa 135, and a back surface 133t of the connecting portion 133. Next, the extraction electrode 148 extends on the back surface 132b of the framing portion 132 in the −Z direction to the −X-side and −Z-side of the back surface 132b of the framing portion 132. Note that, the extraction electrode 147 and the extraction electrode 148 are not electrically connected to each other.

The excitation electrodes 145 and 146 and the extraction electrodes 147 and 148 are conductive metal films, which are formed by, for example, plating or sputtering and vacuum evaporation using a metal mask stencil. These metal films have a two-layered structure including a base layer made of a chrome (Cr), a titanium (Ti), a nickel (Ni), an aluminum (Al), a tungsten (W), a nickel-chrome (NiCr) alloy, a nickel-titanium (NiTi) alloy, or a nickel-tungsten (NiW) alloy, which is for increasing adhesion with a quartz-crystal material, and a main electrode layer made of a gold (Au) or a silver (Ag), which is formed on the base layer. Note that, the conductive metal film is not limited to the above-described structure, and may have, for example, a three or more layered structure including a chrome layer (as a base layer), on which a nickel-tungsten alloy is stacked.

### Fabrication Method of Piezoelectric Vibrating Piece

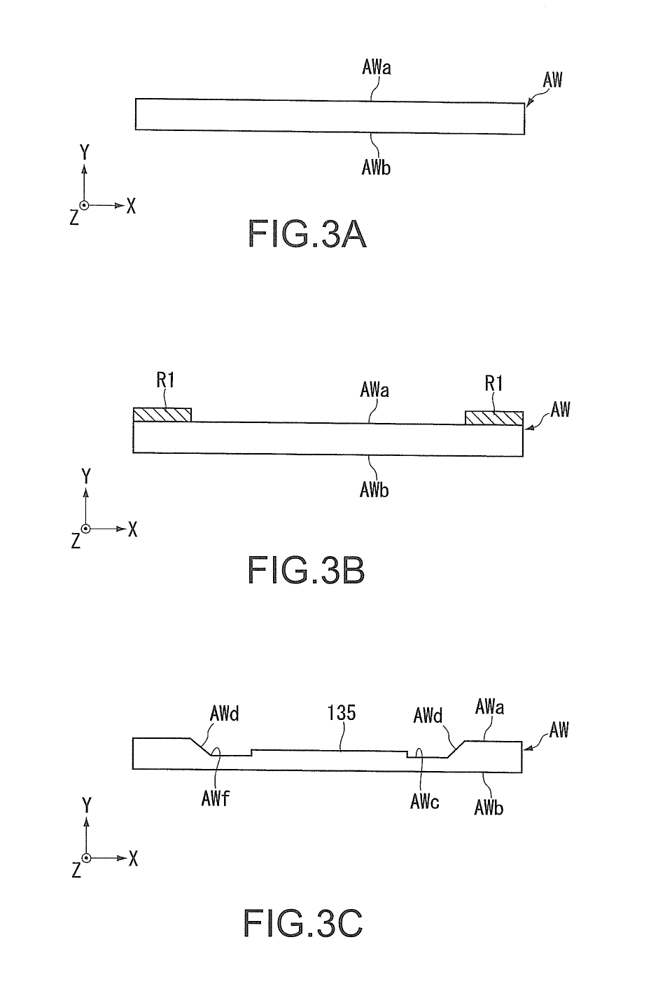

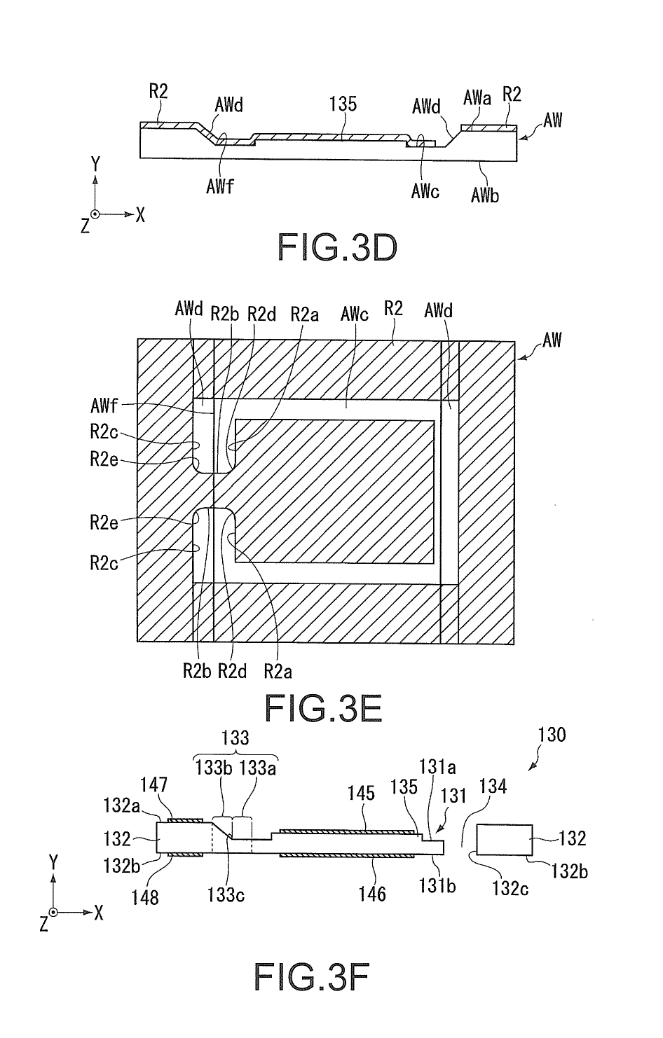

The following description describes a method for fabricating the piezoelectric vibrating piece 130 with reference to FIGS. 3A to 3F. In the fabrication of the piezoelectric vibrating piece 130, a multiple chamfering is performed on a piezoelectric wafer AW from which individual pieces are cut out. Note that, FIGS. 3A to 3F illustrate a fabrication process, in time series, of one of the piezoelectric vibrating pieces 130 formed on the piezoelectric wafer AW, and FIGS. 3A to 3D, and FIG. 3F each correspond to the cross section taken along the line IB-IB in FIG. 1A.

First, as illustrated in FIG. 3A, the piezoelectric wafer AW is prepared. The piezoelectric wafer AW is cut out from a crystalline body by the AT-cut method. The piezoelectric wafer AW may be formed with a predetermined thickness by, for example, being polished. Next, as illustrated in FIG. 3B, a resist pattern R1 is formed on a front surface AWa of the piezoelectric wafer AW. The resist pattern R1 is formed by a photolithography method in which a mask pattern is exposed to be developed after a resist is applied on entire surface of the piezoelectric wafer AW. Note that, a mask pattern made of a metal film may be formed between the resist pattern R1 and the piezoelectric wafer AW. Regarding the mask pattern made of a metal film, the same applies to a resist pattern, which is described later.

Then, the front surface AWa of the piezoelectric wafer AW is wet-etched using a predetermined etchant. Thus, as illustrated in FIG. 3C, a portion that is not coated with the resist pattern R1 is etched, and then the thickness (width in the Y-axis direction) of the portion is decreased, which forms a depressed portion AWc. Since the depressed portion AWc becomes a portion including the vibrating portion 131, the thickness of vibrating portion 131 is appropriately adjusted such that the vibrating portion 131 obtains a desired frequency characteristic. Note that, the mesa 135 is formed by further performing the photolithography method and an etching, after the depressed portion AWc is formed.

During the formation of the depressed portion AWc, inclined surfaces AWd are formed between the depressed portion AWc and the front surface AWa of the piezoelectric wafer AW. The inclined surfaces AWd are formed with the direction of crystallographic axis of the piezoelectric wafer AW, which is a quartz-crystal material, and are respectively formed at both ends of the depressed portion AWc in the X direction. Thus, the inclined surface AWd is a crystal surface generated on the front surface of the piezoelectric wafer AW by wet-etching for making a portion to be the vibrating portion 131 thinner than a portion to be the framing portion 132.

Subsequently, as illustrated in FIG. 3D, a resist pattern R2 is formed on the front surface AWa of the piezoelectric wafer AW. Similarly to the resist pattern R1, the resist pattern R2 is formed by the photolithography method in which a mask pattern is exposed to be developed after a resist is applied on the entire surface of the piezoelectric wafer AW. The resist pattern R2 is a mask pattern for forming the through-hole 134.

FIG. 3E is a view (plan view) of the piezoelectric wafer AW, which is illustrated from the Y-axis direction similarly to FIG. 1A, in a state where the resist pattern R2 illustrated in FIG. 3D is formed. As illustrated in FIG. 3E, the resist pattern R2 has straight line portions R2a, R2b, and R2c, and curved lines R2d and R2e at a portion corresponding to the connecting portion 133 and a peripheral area of the connecting portion 133. The straight line portions R2a, R2b, and R2c may partially include a curved line. The curved lines R2d and R2e may partially include a straight line.

The straight line portion R2a is formed to correspond to an end surface 131c (see FIG. 1A and FIG. 2) at the −X-side of the vibrating portion 131 and is formed along the Z direction. The straight line portion R2b is formed to correspond to the straight line portion 133f (see FIG. 1A, and FIG. 2) of the connecting portion 133 and is formed along the X direction. The straight line portion R2c is formed to correspond to the side surface 132c at the +X-side of the inner circumference of the framing portion 132, and is formed along the Z direction.

The curved lines R2d and R2e respectively correspond to a vibrating portion side corner portion 133d and a framing portion side corner portion 133e (see FIG. 1A and FIG. 2). The curved line R2d connects the straight line portion R2a and the straight line portion R2b. The curved line R2e connects the straight line portion R2b and the straight line portion R2c. At this time, the curved lines R2d and R2e of the resist pattern R2 are disposed such that the curved lines R2d and R2e avoid a boundary portion AWf between the inclined surface AWd and the depressed portion (flat surface) AWc. That is, the resist pattern R2 is formed with disposing the straight line portion R2b at the boundary portion AWf. The straight line portion R2b includes a portion corresponding to the middle region 136c, which is illustrated in FIG. 2. The curved lines R2d and R2e respectively include portions corresponding to the connecting regions 136a and 136b, which are illustrated in FIG. 2.

Then, the piezoelectric wafer AW is wet-etched using a predetermined etchant. As illustrated in FIG. 3F, this forms the through-hole 134, which passes through the piezoelectric wafer AW in the Y-axis direction. By opening the through-hole 134, the vibrating portion 131 having a rectangular shape, the framing portion 132 surrounding the vibrating portion 131, and the connecting portion 133 which connects the vibrating portion 131 and the framing portion 132 are formed.

In addition, as illustrated in FIG. 3F, the excitation electrodes 145 and 146 are respectively formed on the front and back surfaces of the vibrating portion 131, while the extraction electrodes 147 and 148 are respectively formed on the front and back surfaces of the framing portion 132 and the connecting portion 133. The excitation electrodes 145 and 146, and the extraction electrodes 147 and 148 are formed at approximately the same time by depositing a metal layer using, for example, sputtering or vacuum evaporation using a metal mask stencil. The metal film includes, for example, a nickel-tungsten layer as a base layer, and a gold film, which is formed on the base layer as a main electrode layer. Note that, the metal film may include a chrome layer (as a base layer) on which a nickel-tungsten layer is formed. As described above, the piezoelectric vibrating piece 130 is completed.

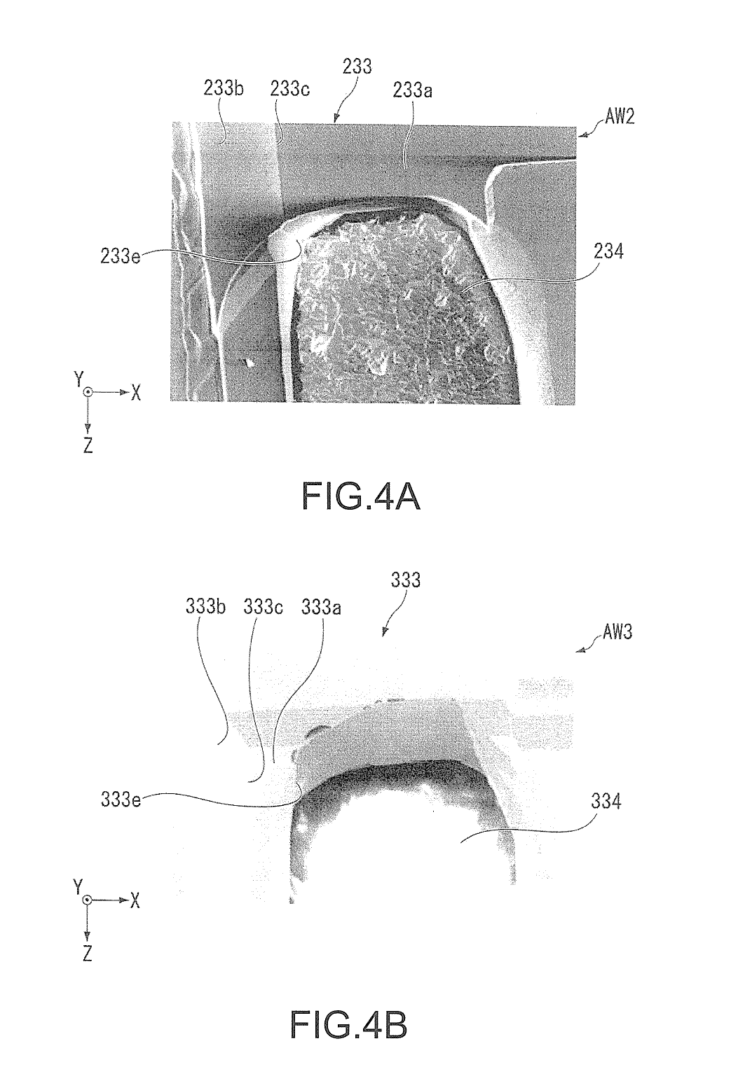

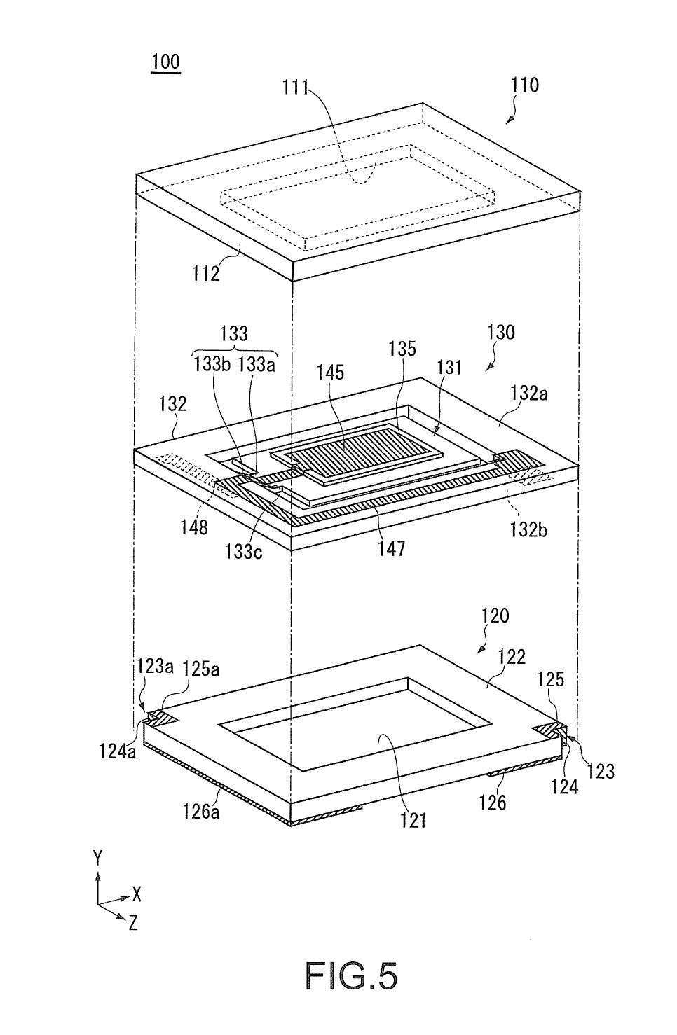

FIG. 4A is a view illustrating a configuration of a piezoelectric wafer AW2 according to a comparative example. FIG. 4A is an enlarged view illustrating a framing portion side corner portion 233e of a connecting portion 233. The framing portion side corner portion 233e corresponds to the framing portion side corner portion 133e of the connecting portion 133 illustrated in FIGS. 1A and 1B. As illustrated in FIG. 4A, a boundary portion 233c between a flat surface 233a and an inclined surface 233b is formed at a position partially including the framing portion side corner portion 233e. That is, FIG. 4A illustrates a through-hole 234 opened by etching the piezoelectric wafer AW2 with the curved lines R2d and R2e of the resist pattern R2 overlapped with the boundary portion AWf illustrated in FIG. 3F. As illustrated in FIG. 4A, in this case, the framing portion side corner portion 233e of the piezoelectric wafer AW2 is etched toward the −Z and −X directions (white portion in FIG. 4A), and it is observed that the front surfaces of the flat surface 233a and the inclined surface 233b are partially eroded.

FIG. 4B is a view illustrating a configuration of a piezoelectric wafer AW3 according to a reference example. FIG. 4B is an enlarged view illustrating a framing portion side corner portion 333e of the connecting portion 333. Note that, FIG. 4B illustrates a boundary portion 333c between a flat surface 333a and an inclined surface 333b disposed at a framing portion side. In this reference example, the boundary portion 333c is not disposed in a connecting portion 333, however, this example illustrates a case in which the boundary portion 333c is not disposed in the framing portion side corner portion 333e. As illustrated in FIG. 4B, in this case, the framing portion side corner portion 333e is not etched toward the −Z and the −X directions, and it is observed that the front surface of the flat surface 333a is not eroded.

According to FIGS. 4A and 4B, if the piezoelectric wafer AW3 is etched in a state where the boundary between the flat surface and the inclined surface is disposed at the curved line of the mask pattern, the etching progresses under a back side of the mask pattern, then parts of the framing portion and the connecting portion are eroded as illustrated in FIG. 4A.

In this embodiment, the curved lines R2d and R2e of the resist pattern R2 are disposed such that the curved lines R2d and R2e avoid the boundary portion AWf. This allows preventing etching from progressing in the Z direction at the framing portion side corner portion 133e of the connecting portion 133. This can avoid eroding parts of the framing portion 132 and the connecting portion 133, and can prevent decrease in shock resistance by keeping rigidity of the connecting portion 133. In addition, production of inferior products is minimized, which results in efficient production of the piezoelectric vibrating pieces.

### Piezoelectric Device

The following description describes an embodiment of a piezoelectric device. As illustrated in FIG. 5, a piezoelectric device 100 includes a lid 110, a base 120, and the piezoelectric vibrating piece 130. The lid 110 is bonded to the +Y-side of the piezoelectric vibrating piece 130, and the base 120 is bonded to the −Y-side of the piezoelectric vibrating piece 130 such that the lid 110 and the base 120 sandwich the piezoelectric vibrating piece 130. The piezoelectric vibrating piece 130 illustrated in FIGS. 1A and 1B is used as the piezoelectric vibrating piece 130 of the embodiment. Similarly to the piezoelectric vibrating piece 130, the lid 110 and the base 120 are made of, for example, an AT-cut quartz-crystal material. For the lid 110 and the base 120, use of a material same as that of the piezoelectric vibrating piece 130 avoids making difference in constant thermal expansion coefficients between them.

As illustrated in FIG. 5, the lid 110 is a plate-shaped member having a rectangular shape, and includes a depressed portion 111, which is disposed on the back surface (−Y-side surface), and the bonding surface 112, which surrounds the depressed portion 111. Note that, it is arbitrary whether or not disposing the depressed portion 111 on the back surface of the lid 110, and the depressed portion 111 may not be required if the piezoelectric vibrating piece 130 is thinner than the framing portion 132, similarly to the vibrating portion 131 of the piezoelectric vibrating piece 130. The bonding surface 112 faces the front surface 132a of the framing portion 132 of the piezoelectric vibrating piece 130.

The lid 110 is bonded to the front surface (+Y-side surface) of the piezoelectric vibrating piece 130 via a bonding material (not shown) disposed between the bonding surface 112 of the lid 110 and the front surface 132a of the framing portion 132. For example, a non-conductive low melting point glass is used as a bonding material. Alternatively, a resin such as a polyimide may be used as a bonding material. In addition, the bonding surface 112 and the front surface 132a may be directly bonded to each other.

As illustrated in FIG. 5, the base 120 is a plate-shaped member having a rectangular shape, and includes a depressed portion 121, which is disposed on the front surface (+Y-side surface), and the bonding surface 122, which surrounds the depressed portion 121. The bonding surface 122 faces the back surface 132b of the framing portion 132 of the piezoelectric vibrating piece 130. The base 120 is bonded to the back surface (−Y-side surface side) of the piezoelectric vibrating piece 130 via a bonding material (not shown) disposed between the bonding surface 122 and the back surface 132b of the framing portion 132. In addition, the bonding surface 122 and the back surface 132b may be directly bonded to each other.

Castellations 123 and 123a, which are cutouts, are disposed at two diagonal corners (a corner at the +X-side and +Z-side, and a corner at the −X-side and −Z-side) of the four corners of the base 120. Also, external electrodes 126 and 126a are disposed as a pair of mounting terminals on the back surface (the −Y-side surface) of the base 120. Castellation electrodes 124 are 124a are respectively disposed at the castellations 123 and 123a. Further, connecting electrodes 125 and 125a are respectively disposed at regions, on the front surface (+Y-side surface) of the base 120, surrounding the castellations 123 and 123a. The connecting electrodes 125 and 125a are respectively electrically connected to the external electrodes 126 and 126a via the castellation electrodes 124 and 124a. Note that, the castellations 123 and 123a are not limited to be disposed at corners, and may be disposed at sides.

The castellation electrodes 124 and 124a, the connecting electrodes 125 and 125a, and the external electrodes 126 and 126a are integrally formed by depositing a conductive metal film by sputtering or vacuum evaporation using, for example, a metal mask stencil. Note that, these electrodes can be formed separately. In addition, the electrodes have a two-layered metal film including, for example, a nickel-tungsten layer and a gold layer deposited in this order, or the electrode have a three-layered metal film including a chromium layer, a nickel-tungsten layer, and a gold layer deposited in this order.

A reason why a chrome is used in the three-layered metal film is that the chrome has a high adhesion property to a quartz-crystal material, and spreads into a nickel-tungsten layer to form an oxidation film (passive film) at the exposed surface to enhance the corrosion resistance of the metal film.

Note that, the metal film can include, for example, an aluminum (Al), a titanium, or their alloy instead of a chrome. In addition, the meal film can include, for example, a nickel, or a tungsten (W) instead of a nickel-tungsten alloy. Also, the metal film can include, for example, a silver instead of a gold.

The connecting electrode 125 of the base 120 is electrically connected to the extraction electrode 147, which extends to the back surface of the piezoelectric vibrating piece 130. Meanwhile, the connecting electrode 125a is electrically connected to the extraction electrode 148 of the piezoelectric vibrating piece 130. Note that, on the base 120, the connections between the connecting electrodes 125 and 125a and the external electrodes 126 and 126a is not limited to the connection via the castellations 123 and 123a, and the connecting electrodes 125 and 125a may be respectively connected to the external electrodes 126 and 126a via, for example, through electrodes, which pass through the base 120 in the Y-axis direction.

### Fabrication Method of Piezoelectric Device

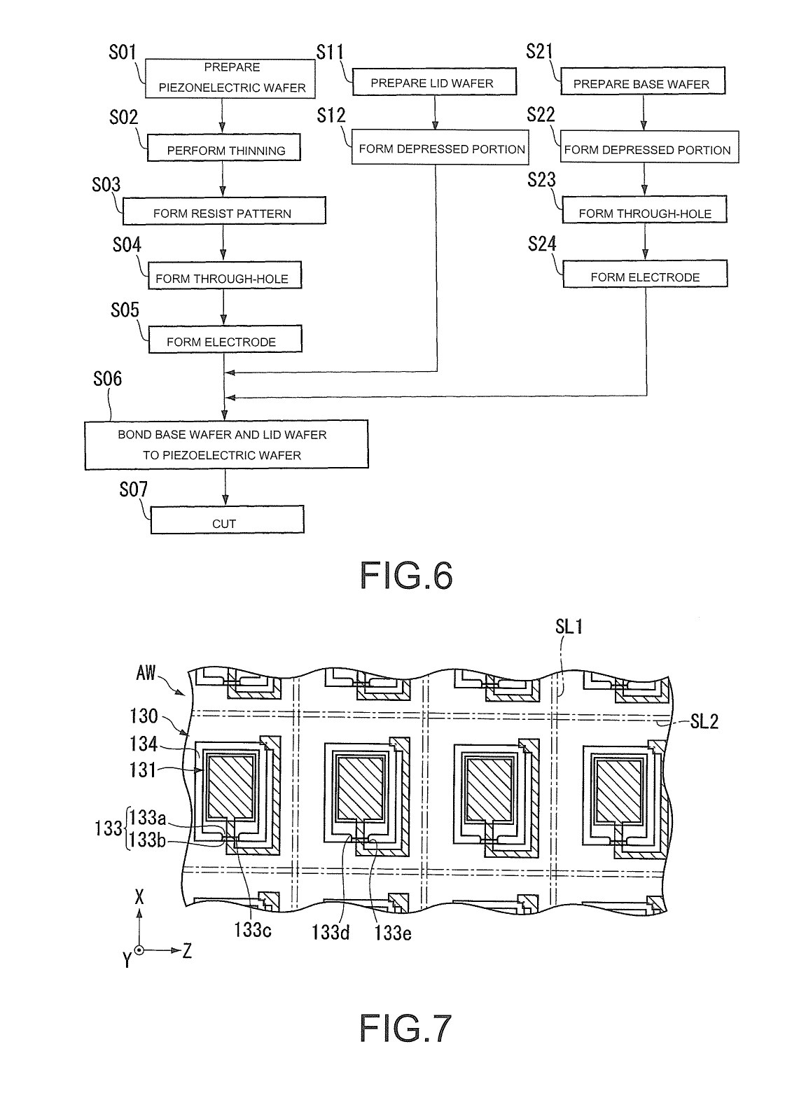

The following description describes a method for fabricating the piezoelectric device 100 with reference to FIGS. 6 to 9. FIG. 6 is a flowchart of a fabrication process of the piezoelectric device 100. Various steps for fabricating the piezoelectric wafer AW (fabrication method of piezoelectric vibrating piece 130) are similar to the above-described steps.

That is, as illustrated in FIG. 6, the process includes: preparing a piezoelectric wafer AW (step S01, see FIG. 3A), thinning the center portion of the piezoelectric wafer AW (step S02, see FIGS. 3B and 3C), forming a resist pattern R2 on the piezoelectric wafer AW (step S03, see FIGS. 3D and 3E), opening the through-hole 134 on the piezoelectric wafer AW (step S04, see FIG. 3F), and forming electrodes on vibrating portion 131 or similar portion (step S05, see FIG. 3F). Thus, as illustrated in FIG. 7, the components of the piezoelectric vibrating piece 130 are disposed in a matrix to form the piezoelectric wafer AW. Note that, the mesa 135 is omitted in FIG. 7.

Also, the lid 110 and the base 120 are fabricated along with the fabrication of the piezoelectric wafer AW. Similarly to the piezoelectric vibrating piece 130, in the fabrication of the lid 110 and the base 120, a multiple chamfering is performed on a lid wafer LW and a base wafer BW from which individual pieces are cut out.

First, similarly to the piezoelectric wafer AW, the lid wafer LW and the base wafer BW are each prepared as illustrated in FIG. 6 (steps S11 and S21). Similarly to the piezoelectric wafer AW, each wafer is cut out from a crystalline body by the AT-cut method. In the fabrication process of the piezoelectric device 100, each wafer is heated, and thermally expanded in a step for bonding the wafers and a step for forming a metal film on the front surface of the wafers. Using wafers of different materials with different thermal expansion coefficients may result in deformation or cracking due to the difference in thermal expansion coefficient. This is a reason why each wafer is cut out from a crystalline body.

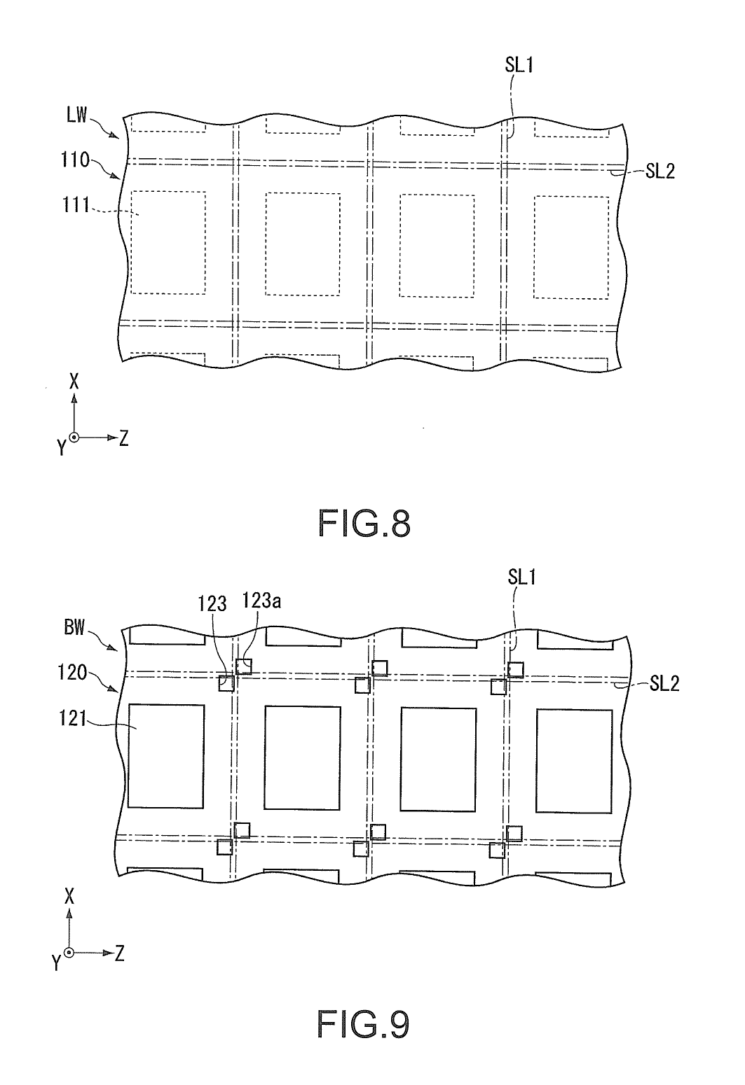

The depressed portion 111 is formed on the back surface of the lid wafer LW by a photolithography method and etching (step S12). Thus, the lid wafer LW is formed with the depressed portions 111, which are disposed in a matrix as illustrated in FIG. 8. The depressed portions 121 are formed on the front surface of the base wafer BW by a photolithography method and etching (step S22). Subsequently, through-holes, which correspond to the castellations 123 and 123a are formed on the base wafer BW (step S23).

Further, the castellation electrodes are formed on the side surfaces of the through-holes in the base wafer BW, connecting electrodes are formed on the front surface of the base wafer BW, and external electrodes are formed on the back surface of the base wafer BW. The castellation electrode, the connecting electrode, and the external electrode are each formed by sputtering or vacuum evaporation using, for example, a metal mask stencil (step S24). Thus, the base wafer BW is formed, on which each component is disposed in a matrix as illustrated in FIG. 8. Note that, the electrodes are omitted in FIG. 8. In addition, the depressed portions 111 and 121 of the lid wafer LW and the base wafer BW may also be formed by a machining process instead of etching.

Subsequently, the lid wafer LW illustrated in FIG. 8 is bonded to the front surface of the piezoelectric wafer AW illustrated in FIG. 7 via a bonding material, while the base wafer BW illustrated in FIG. 9 is bonded to the back surface of the piezoelectric wafer AW via a bonding material under the vacuum atmosphere (step S06). The bonding material such as a low melting point glass, which is heated to be molten, is applied, then is solidified to the wafers. Note that, the piezoelectric wafer AW may be bonded to the lid wafer LW and the base wafer BW directly instead of using the bonding material.

After that, the bonded wafer is diced along scribe lines SL1 and SL2, which are established in advance using, for example, a dicing saw (step S07). Finally, the individual piezoelectric devices 100 are completed.

Thus, since the above-described piezoelectric device includes the piezoelectric vibrating piece 130 that prevents decrease in shock resistance, the piezoelectric device with enhanced durability or reliability can be provided. The generation of inferior products of the piezoelectric vibrating piece 130 is decreased, which results in efficient production of the piezoelectric device.

Above all, the embodiments of this disclosure are described, however, this disclosure is not limited to the above-described explanations, and various kinds of modifications can be made without departing the scope of the disclosure.

In addition, while in the above-described embodiment, a crystal unit (piezoelectric resonator) is described as a piezoelectric device, and the piezoelectric device may be an oscillator. If the oscillator is used, the base 120 includes an Integrated Circuit (IC) or similar circuit, and an extraction electrode 141 or similar electrode of the piezoelectric vibrating piece 130, and the external electrodes 126 and 126a of the base 120 are each connected to the IC or similar circuit. In addition, while in the above-described embodiment, an AT-cut quartz-crystal material, which is similar to the piezoelectric vibrating piece 130, is used as the lid 110 and the base 120, however another type of quartz-crystal material, a glass, a ceramic or similar material may be used instead of the AT-cut quartz-crystal material.

In the piezoelectric vibrating piece, the boundary may be disposed at approximately center of the connecting portion.

A method for fabricating a piezoelectric vibrating piece according to the disclosure includes: forming a through-hole in a substrate to form the piezoelectric vibrating piece including a vibrating portion, a framing portion surrounding the vibrating portion, and a connecting portion connecting the vibrating portion and the framing portion. A mask pattern for forming the through-hole has straight line portions and a curved line, and the curved line connects the straight line portions. The mask pattern is formed by disposing the straight line portion at a boundary between an inclined surface and a flat surface, and the inclined surface and the flat surface are formed on the substrate. In the method, the boundary may be disposed on at least one of a front surface and a back surface of the connecting portion. The inclined surface may be formed by making the vibrating portion of the substrate thinner than the framing portion.

A piezoelectric device may include the piezoelectric vibrating piece. A method for fabricating a piezoelectric device may include bonding the lid and the base respectively to a front surface and a back surface of the framing portion of the piezoelectric vibrating piece.

According to this disclosure, a boundary between the inclined surface and the flat surface is established in a middle region. Accordingly, the boundary is not formed in a connecting region, which allows preventing decrease in rigidity of the connecting portion and provides high reliability of a piezoelectric vibrating piece and a piezoelectric device. In addition, the curved line of the mask pattern for opening the through-hole is disposed away from the boundary. Accordingly, the connecting portion and the framing portion are not eroded carelessly, which allows reducing inferior products to enhance the production efficiency of a piezoelectric vibrating piece or a piezoelectric device.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric vibrating piece, comprising:
a vibrating portion;
a framing portion, surrounding the vibrating portion; and
a connecting portion, connecting the vibrating portion and the framing portion, wherein
the connecting portion includes an inclined surface disposed on at least one of a front surface and a back surface of the connecting portion, and
a boundary between the inclined surface and a flat surface is established in a middle region that is away from a connecting region of the connecting portion and the vibrating portion, and is away from a connecting region of the connecting portion and the framing portion.

2. The piezoelectric vibrating piece according to claim 1, wherein
the boundary is disposed at approximately center of the connecting portion.

3. A method for fabricating the piezoelectric vibrating piece according to claim 1, comprising:
forming a through-hole in a substrate to form the piezoelectric vibrating piece including a vibrating portion, a framing portion surrounding the vibrating portion, and a connecting portion connecting the vibrating portion and the framing portion, wherein
a mask pattern for forming the through-hole has straight line portions and a curved line, and the curved line connecting the straight line portions, and
the mask pattern is formed by disposing the straight line portion at a boundary between an inclined surface and a flat surface, and the inclined surface and the flat surface being formed on the substrate.

4. The method for fabricating a piezoelectric vibrating piece according to claim 3, wherein
the boundary is disposed on at least one of a front surface and a back surface of the connecting portion.

5. The method for fabricating a piezoelectric vibrating piece according to claim 3, wherein
the inclined surface is formed by making the vibrating portion of the substrate thinner than the framing portion.

6. A piezoelectric device, comprising
the piezoelectric vibrating piece according to claim 1.

7. A method for fabricating a piezoelectric device, comprising
bonding the lid and the base respectively to a front surface and a back surface of the framing portion of the piezoelectric vibrating piece according to claim 1.
